(19) United States
(12) Patent Application Publication
(10) Pub. No.: US 2025/0048939 A1
(43) Pub. Date: Feb. 6, 2025

(54) SYSTEM FOR DEFORMING AN EFFECTIVE STRUCTURE

(71) Applicants: NELUMBO DIGITAL, Crolles (FR); EUROPEAN SYNCHROTRON RADIATION FACILITY, Grenoble (FR)

(72) Inventors: Yves-Matthieu Le Vaillant, Crolles (FR); Tobias Schülli, Grenoble (FR)

(21) Appl. No.: 18/713,558

(22) PCT Filed: Nov. 16, 2022
(86) PCT No.: PCT/EP2022/082167

§ 371 Date: Jul. 31, 2024

(30) Foreign Application Priority Data
Nov. 26, 2021 (FR) FR2112600

(51) Int. Cl. H10N 70/20; H01L 21/66; H10N 70/00

(52) U.S. Cl. CPC H10N 70/20; H01L 22/12; H10N 70/061

(57) ABSTRACT

A system, for deforming an effective structure, includes a stack, compression means, and shear means. The stack includes, successively, the effective structure and a buffer matrix. Between the effective structure and the buffer matrix is an interface having a mean plane. The compression means is designed to apply a compressive force to the stack along an axis normal to the mean plane of the interface. The shear means is designed to apply to the buffer matrix longitudinal shear forces parallel to the mean plane of the interface. The buffer matrix is designed to transmit the shear forces to the effective structure in the mean plane of the interface so as to deform the effective structure.

### CROSS-REFERENCE TO RELATED APPLICATIONS

This application is a national phase entry under 35 U.S.C. § 371 of International Patent Application PCT/EP2022/082167, filed Nov. 16, 2022, designating the United States of America and published as International Patent Publication WO 2023/094244 A1 on Jun. 1, 2023, which claims the benefit, under Article 8 of the Patent Cooperation Treaty, of French Patent Application Serial No. FR2112600, filed Nov. 26, 2021.

### TECHNICAL FIELD

The disclosure relates to the technical field of the engineering and science of deformations imposed on a material.

The disclosure finds its application, in particular, in:
the operando characterization of the deformation of the material;
the fabrication of an advanced substrate or of a component including the deformed material; and
the fabrication of a tunable component including the deformed material, enabling tuning of the deformation of the material during the functioning of the component.

### BACKGROUND

The deformation of a material can strongly affect its physical properties.

In particular, semiconductor type materials undergo under deformation a notable modification of their electron band structure that can lead to:
modification of the mobility of the carriers;
regular modification of the energy of the forbidden band, possibly even leading to a transition of its type from indirect to direct; and
regular modification of the energy barrier of the heterostructures (or even the quantum wells).

These changes of electronic properties can bring about significant potential advantages.

The deformation of perovskite type materials can modify even more spectacularly their physical properties, in particular with changes of phase leading, for example, to the appearance of ferroelectricity or ferromagnetism.

A known prior art system for deforming an effective structure includes apparatus including diamond anvils. The apparatus includes:
the effective structure to be deformed;
two anvils made of a hard material (typically diamond, sapphire or ruby) on either side of the effective structure; and
compression means designed to apply a compression force to the anvils along a compression axis.

A prior art system of this kind is not entirely satisfactory in that:
(i) obtaining deformation in tension of the effective structure along an axis perpendicular to the compression axis necessitates the exertion of considerable pressure on the anvils (of the order of several hundred atmospheres);
(ii) the deformation in tension obtained remains very limited (for example, of the order of 0.05%), despite the high pressure exerted on the anvils; and
(iii) the effective structure must have a high mechanical strength to withstand the high pressure.

### BRIEF SUMMARY

Embodiments of the disclosure aim to remedy some or all of the aforementioned disadvantages. To this end, an object of the disclosure is a system for deforming an effective structure, including:
a stack comprising successively the effective structure and a buffer matrix, the stack having an interface between the effective structure and the buffer matrix, the interface having a mean plane;
compression means designed to apply a compressive force to the stack along an axis normal to the mean plane of interface; and
shear means designed to apply to the buffer matrix longitudinal shear forces parallel to the mean plane of the interface;

the buffer matrix being designed to transmit the shear forces to the effective structure in the mean plane of the interface so as to deform the effective structure.

### Definitions

By “deforming” is meant modifying the stress state. By “stress state” is meant the stresses resulting from internal forces operative between the deformed parts of the effective structure, the internal forces being either tension forces or compression forces. If the internal forces are zero or quasi zero, the expression relaxed state is used to designate the corresponding stress state.

By “effective structure” is meant a structure including a material to be deformed. The effective structure may be a component. The effective structure may be a structure from which a component will be fabricated. The component may be intended for applications in particular in the fields of microelectronics, optics, optoelectronics, piezoelectrics, ferroelectrics, anti-ferroelectrics, pyroelectrics or spintronics.

By “stack” is meant a succession of elements in a vertical direction.

By “successively” is meant from the lowest level of the stack to the highest level of the stack.

By “buffer matrix” is meant a material covering the effective structure in such a manner as to smooth the local variations of stress exerted on the effective structure during compression of the stack.

By “mean plane” is meant a reference plane at 3 points on the contact surface (defining the interface between the effective structure and the buffer matrix), as defined in the standard ASTM F534, § 3.1.2. for the measurement of a bow or in the standard ASTM F1390 for the measurement of a warp.

Accordingly, in contrast to the prior art, a system of this kind, in accordance with embodiments of the disclosure, enables deformation of an effective structure including a fragile material to be deformed thanks to the presence of a buffer matrix of this kind. In fact, the buffer matrix enables improvement of the homogeneity of the loading of the effective structure, thereby limiting the risks of rupture of the material to be deformed.

Furthermore, the shear means allow much greater deformation of the effective structure along an axis perpendicular to the compression axis than in the prior art.

Moreover, the conjoint action of the shear means and the compression means make it possible to increase the strength of the interface between the effective structure and the buffer matrix by reducing the risks of delamination and improving the effectiveness with which shear forces are transmitted to the effective structure.

The system, in accordance with embodiments of the disclosure, may have one or more of the following features.

In accordance with one feature of the disclosure, the shear means include a member for holding the buffer matrix mobile in translation in a longitudinal direction parallel to the mean plane of the interface.

Thus, one advantage obtained is to obtain shear means external to the stack that can be used easily in an industrial context.

In accordance with one feature of the disclosure, the shear means include an articulated parallelogram designed to move the holding member in translation in the longitudinal direction.

Thus, an advantage obtained by means of a mechanism with four bars (articulated to one another by pivot connections) is its simplicity in obtaining movement in translation.

In accordance with one feature of the disclosure, the holding member is mobile in rotation about a rotation axis perpendicular to the mean plane of the interface.

Thus, one advantage obtained is to be able to control the longitudinal axis of the shear forces applied to the buffer matrix in the plane parallel to the mean plane of the interface between the effective structure and the buffer matrix.

In accordance with one feature of the disclosure, the stack includes a rubbery layer, the buffer matrix being between the effective structure and the rubbery layer and the shear means include the rubbery layer, the rubbery layer being designed to convert the compression force into longitudinal shear forces parallel to the mean plane of the interface applied to the buffer matrix.

### Definitions

By “layer” is meant a layer or a plurality of sub-layers of the same kind.

By “rubbery” is meant that the layer is made of a material based on a natural or synthetic rubber. By “based on” is meant that the rubber is the main and majority material constituting the layer.

Thus, an advantage obtained by the rubbery layer is to obtain shear means internal to the stack. The rubbery layer is highly effective in converting the compression force (normal to the mean plane of the interface) into longitudinal shear forces (parallel to the mean plane of the interface). In fact, a rubbery layer has interesting properties of elasticity and incompressibility with a Young's modulus between 1 MPa and 100 MPa inclusive and a Poisson coefficient close to 0.5. Furthermore, the rubbery layer makes possible great homogeneity of the loading of the buffer matrix, thereby leading to good homogeneity of the deformation of the effective structure.

It is possible to demonstrate (cf. formula below) that the pressure exerted on the stack by the compression means and the thickness of the rubbery layer are the main two parameters enabling adjustment of a target deformation for the effective structure:

$${σ}_{V} ( {ε}_{L} ) = {ε}_{L} ( \frac{32 {ES}^{2} {s}_{L}}{\frac{64}{3} {ES}^{2} h + 3 {s}_{L}} + \frac{4}{3} ( 1 + 2 {S}^{2} ) E ( 1 + \frac{3 {s}_{L}}{16 {ES}^{2} h} ) + \frac{{s}_{L}^{2}}{\frac{32}{9} {ES}^{2} h + \frac{2}{3} {s}_{L} h} ) ,$$

where:
σᵥ is the pressure linked to the compression force exerted on the stack normal to the interface,
ε_{L} is the isotropic biaxial deformation of the effective structure/buffer matrix combination,
E is the Young's modulus of the rubbery layer,
h is the height of the rubbery layer considered as of cylindrical shape,

$$S = \frac{π {r}^{2}}{2 π rh} = \frac{r}{2 h} ,$$

where r is the radius of the rubbery layer considered as of cylindrical shape, and
S_{L}=E′_{L}t_{L}, where E′_{L} is the biaxial modulus of elasticity of the effective structure/buffer matrix combination and t_{L} is the thickness of the effective structure/buffer matrix combination.

The choice of a small thickness for the rubbery layer must be compensated by a high pressure to be exerted on the stack. The choice of a large thickness for the rubbery layer enables reduction of the pressure required for a given lateral deformation. Contrarily, a higher pressure favors friction, potentially useful for preventing sliding between the buffer matrix and the effective structure or between the buffer matrix and the rubbery layer.

Such shear means internal to the stack can be combined with shear means external to the stack, which makes it possible to envisage biaxial (and possibly anisotropic) deformations of the effective structure in the mean plane of the interface between the effective structure and the buffer matrix.

In accordance with one feature of the disclosure, the rubbery layer is made of a material chosen from:
a silicone type polymer preferably including polydimethylsiloxane;
vinyl ethylene acetate;
polyurethane;
polyacrylic;
butadiene;
a compound including a butyl group;
a rubber of EPDM type;
a fluoroelastomer, in particular a perfluoroelastomer;
isoprene;
a compound including a nitrile group;
polychloroprene; and
styrene-butadiene.

### Definition

“EPDM” is the abbreviation of ethylene-propylene-diene monomer.

A particular advantage of polydimethylsiloxane (PDMS) is its high optical transparency in the visible band and in the near infrared, which is an interesting property for optical characterization of the deformation of the effective structure.

In accordance with one feature of the disclosure, the buffer matrix has a Young's modulus greater than or equal to 1 GPa.

Thus, one advantage obtained is to obtain a buffer matrix that is resilient in the face of the compression force exerted on the stack. The material of the buffer matrix is advantageously chosen to have a Young's modulus matching the Young's modulus of the effective structure so that the Young's modulus gradient is as low as possible in order to reduce the risks of cracking of the effective structure linked to locally heterogeneous deformation. The quantity corresponding to the thickness multiplied by the Young's modulus is preferably chosen to be of the same order of magnitude for the buffer matrix and for the effective structure.

In accordance with one feature of the disclosure, the effective structure has a deformation rate at rupture denoted τ_{R1} and the buffer matrix has a deformation rate at rupture denoted τ_{R2} satisfying the condition τ_{R2}>τ_{R1}.

Thus, one advantage obtained is to protect the effective structure from cleavage or rupture during compression of the stack.

In accordance with one feature of the disclosure, the buffer matrix is made of a material chosen from:
a polymer, preferably a polyimide, polycarbonate, polyetherimide, polyamide-imide, polyethylene, glass, polyetheretherketone, polypropylene, polymethylmethacrylate, polyethersulfone, polyvinyl chloride, polystyrene, polyethylene terephthalate; and
a ceramic, preferably SIN, SiC, Al₂O₃.

In accordance with one feature of the disclosure, the effective structure is chosen from:
a structure based on a semiconductor type material;
a structure based on a perovskite type material;
a photonic crystal type structure;
a structure based on a composite material;
a crystal;
a metal;
a polymer;
a ceramic;
chalk; and
cement.

### Definition

By “based on” is meant that the corresponding material is the main and majority material constituting the structure.

In accordance with one feature of the disclosure, the compression means include a lower plate and an upper plate designed to fit tightly around the stack.

### Definition

The terms “lower” and “upper” designate the relative position of the corresponding plates (relative to the stack in a vertical direction). The lower plate is situated below the stack whereas the upper plate is situated above the stack.

In accordance with one feature of the disclosure, the upper plate has a non-plane surface of contact with the rubbery layer, the non-plane contact surface being geometrically designed so that the rubbery layer converts the compression force into longitudinal shear forces parallel to the mean plane of the interface applied anisotropically to the buffer matrix.

Thus, one advantage obtained is to allow anisotropic biaxial deformation of the effective structure in the mean plane of the interface between the effective structure and the buffer matrix without necessitating the presence of shear means external to the stack.

In accordance with one feature of the disclosure, the stack includes an anti-sliding layer between the effective structure and the buffer matrix, the anti-sliding layer having a coefficient of friction designed to hold the effective structure in position in the stack.

Thus, one advantage obtained is to prevent sliding of the buffer matrix on the effective structure and the buffer matrix coming into direct contact with the effective structure.

In accordance with one feature of the disclosure, the stack includes a bonding film between the effective structure and the buffer matrix.

Thus, one advantage obtained is to prevent sliding of the buffer matrix on the effective structure and the buffer matrix coming into direct contact with the effective structure.

The disclosure also has for object an assembly for characterization of an effective structure to be deformed, including:
a system in accordance with embodiments of the disclosure; and
a characterization instrument designed to measure the deformation of the effective structure, the characterization instrument preferably being chosen from:
   a spectroscope, preferably an X-ray diffractometer, a Raman spectrometer, a photoluminescence spectroscope, and/or a reflectance spectroscope; and
   an instrument for measuring electrical resistivity, preferably by the four-point method or by the Van der Pauw method.

Thus, one advantage obtained is to be able to obtain an operando characterization of the deformation of the effective structure, that is to say a measurement during deformation of the effective structure.

In accordance with one feature of the disclosure:
the compression means include a lower plate and an upper plate arranged to fit tightly around the stack;
the stack includes:
   a first rubbery layer between the buffer matrix and the upper plate;
   a second rubbery layer between the lower plate and the effective structure; and
   the stack having an additional interface between the effective structure and the second rubbery layer, the additional interface having a mean plane;
the shear means include the first rubbery layer, the first rubbery layer being designed to convert the compression force into longitudinal shear forces parallel to the mean plane of the interface applied to the buffer matrix; and
the second rubbery layer is designed to convert the compression force into longitudinal shear forces applied to the effective structure in the mean plane of the additional interface.

Thus, one advantage obtained by such first and second rubbery layers is to obtain a high level of deformation of the effective structure along an axis perpendicular to the compression axis.

The disclosure also has for object an assembly for fabrication of a deformed effective structure on a support substrate, the fabrication assembly including:
a system in accordance with embodiments of the disclosure;
the support substrate; and
the stack being formed on the support substrate.

Thus, one advantage obtained is to be able to fabricate an advanced substrate or a component including the deformed material of the effective structure. The compression of the stack enables sliding of the effective structure on the support substrate and bonding thereof in such a manner as to maintain the deformation. It is also possible to obtain a tunable component including the deformed material, enabling tuning of the deformation of the material during the functioning of the component. For example, if the effective structure is a photonic crystal, the deformation can lead to modification of the period of the nanostructures.

In accordance with one feature of the disclosure, the stack includes a layer of air below the effective structure designed to space the effective structure from the support substrate.

Thus, one advantage obtained is to eliminate friction forces between the support substrate and the effective structure so as not to brake the deformation of the effective structure.

In accordance with one feature of the disclosure, the support substrate is permeable to air, the fabrication assembly including circulation means designed to cause a flow of air to circulate from the support substrate toward the layer of air so that the flow of air generates a sustentation force holding the effective structure in position in the stack.

Thus, one advantage obtained is to use the layer of air as an air cushion in order to retain the effective structure in position in the stack.

In accordance with one feature of the disclosure, the circulation means include a regulator designed to regulate the flow of air circulating in the layer of air.

Thus, one advantage obtained is to be able to control the sustentation force of the flow of air.

The disclosure has for object an assembly for fabrication of a deformed effective structure on a support substrate, the fabrication assembly including:
a stack comprising successively the support substrate, a bonding film, the effective structure and a buffer matrix, the stack having an interface between the effective structure and the buffer matrix, the interface having a mean plane;
compression means designed to apply a compressive force to the stack along an axis normal to the mean plane of interface; and
shear means designed to apply to the buffer matrix longitudinal shear forces parallel to the mean plane of the interface;

the buffer matrix being designed to transmit the shear forces to the effective structure in the mean plane of the interface so as to deform the effective structure.

In accordance with one feature of the disclosure, the fabrication assembly includes a detachment layer between the bonding film and the effective structure, the detachment layer being designed to detach the support substrate when the detachment layer is subjected to a heat treatment.

In accordance with one feature of the disclosure, the bonding film is made of a polymer material, the fabrication assembly including emission means designed to emit electromagnetic radiation through the support substrate in such a manner as to irradiate the bonding film, the support substrate being transparent to the electromagnetic radiation.

### BRIEF DESCRIPTION OF THE DRAWINGS

Other features and advantages will become apparent in the detailed description of embodiments of the disclosure, the description including examples and referring to the accompanying drawings.

FIG. 1A is a schematic cross-sectional view of a system, in accordance with embodiments of the disclosure, for equipping a characterization assembly before compression of the stack.

FIG. 1B is a cross-sectional view analogous to FIG. 1A during compression of the stack.

FIG. 2A is a cross-sectional view analogous to FIG. 1A showing the presence of an anti-sliding layer or a bonding film between the effective structure and the buffer matrix.

FIG. 2B is a cross-sectional view analogous to FIG. 2A during compression of the stack.

FIG. 3A is a schematic cross-sectional view of a system, in accordance with embodiments of the disclosure, for equipping a characterization assembly, including shear means external to the stack enabling deformation in tension of the effective structure.

FIG. 3B is a cross-sectional view analogous to FIG. 3A showing the presence of an anti-sliding layer or a bonding film between the effective structure and the buffer matrix.

FIG. 4A is a schematic cross-sectional view of a system, in accordance with embodiments of the disclosure, for equipping a characterization assembly showing the presence of shear means external to the stack enabling deformation in compression of the effective structure.

FIG. 4B is a cross-sectional view analogous to FIG. 4A showing the presence of an anti-sliding layer or a bonding film between the effective structure and the buffer matrix.

FIG. 5A is a schematic cross-sectional view of a characterization assembly, in accordance with embodiments of the disclosure.

FIG. 5B is a cross-sectional view analogous to FIG. 5A showing the presence of an anti-sliding layer or a bonding film between the effective structure and the buffer matrix.

FIG. 6A is a schematic cross-sectional view of a fabrication assembly, in accordance with embodiments of the disclosure, before compression of the stack.

FIG. 6B is a cross-sectional view analogous to FIG. 6A during compression of the stack.

FIG. 7A is a cross-sectional view analogous to FIG. 6A showing the presence of an anti-sliding layer or a bonding film between the effective structure and the buffer matrix.

FIG. 7B is a cross-sectional view analogous to FIG. 7A during compression of the stack.

FIG. 8A is a schematic cross-sectional view of a fabrication assembly, in accordance with embodiments of the disclosure, including shear means external to the stack enabling deformation in tension of the effective structure.

FIG. 8B is a cross-sectional view analogous to FIG. 8A showing the presence of an anti-sliding layer or a bonding film between the effective structure and the buffer matrix.

FIG. 9A is a schematic cross-sectional view of a fabrication assembly, in accordance with embodiments of the disclosure, including rotary shear means external to the stack.

FIG. 9B is a cross-sectional view analogous to FIG. 9A showing the presence of an anti-sliding layer or a bonding film between the effective structure and the buffer matrix.

FIG. 10 is a schematic cross-sectional view of a stack of a system, in accordance with embodiments of the disclosure, for equipping a characterization assembly showing an effective structure composed of patterns coated by the buffer matrix.

FIG. 11A is a schematic cross-sectional view of a fabrication assembly, in accordance with embodiments of the disclosure, showing the presence of a layer of air below the effective structure.

FIG. 11B is a schematic cross-sectional view of a fabrication assembly, in accordance with embodiments of the disclosure, showing the presence of an air cushion below the effective structure.

FIG. 12 is a schematic partial view in perspective of a characterization assembly, in accordance with embodiments of the disclosure showing deformation of the effective structure with geometric frustration.

FIG. 13 is a schematic partial view in perspective of a fabrication assembly in accordance with embodiments of the disclosure, showing deformation of the effective structure with geometric frustration.

FIG. 14 is a schematic partial view in perspective of a system, in accordance with embodiments of the disclosure, showing the presence of a rigid material buried in the rubbery layer.

FIG. 15A is a set of schematic partial cross-sectional views of a system, in accordance with embodiments of the disclosure, showing the evolution of the deformation of the rigid material along the axis X in FIG. 14 when the effective structure is relaxed.

FIG. 15B is a set of schematic partial cross-sectional views of a system, in accordance with embodiments of the disclosure, showing the evolution of the deformation of the rigid material along the axis Y in FIG. 14 when the effective structure is relaxed.

FIG. 16A is a graph representing on the abscissa axis the compression force applied to the stack normal to the interface and on the ordinate axis the deformation rate of the effective structure along the axis X in FIG. 14.

FIG. 16B is a graph representing on the abscissa axis the compression force applied to the stack normal to the interface and on the ordinate axis the deformation rate of the effective structure along the axis Y in FIG. 14.

FIG. 17A is a schematic cross-sectional view of a fabrication assembly, in accordance with embodiments of the disclosure, showing the presence of means for emitting electromagnetic (infrared) radiation intended to interact with the bonding (e.g., thermoplastic) film to obtain a sliding interface between the effective structure and the bonding film.

FIG. 17B is a view analogous to FIG. 17A showing compression of the stack to deform the effective structure after obtaining the sliding interface.

FIG. 18A is a schematic cross-sectional view of a fabrication assembly, in accordance with embodiments of the disclosure, showing the presence of a bonding (e.g., heatset) film having a sliding interface with the effective structure.

FIG. 18B is a cross-sectional view analogous to FIG. 18A showing the presence of means for emitting electromagnetic (ultraviolet) radiation intended to interact with the bonding film to fix a deformed state of the effective structure.

FIG. 19A is a schematic cross-sectional view of a system, in accordance with embodiments of the disclosure, showing the presence of a reinforcement integrated into the rubbery layer before compression of the stack.

FIG. 19B is a cross-sectional view analogous to FIG. 19A during compression of the stack.

FIG. 20 is a schematic cross-sectional view of a system, in accordance with embodiments of the disclosure showing an upper plate having a non-plane surface and a rubbery layer surmounted by a layer of polymer having a non-plane surface.

Note that the drawings described hereinabove are schematic and are not necessarily to the same scale to make them easier to read and understand. The sections are normal to the mean plane of the interface between the effective structure and the buffer matrix.

### DETAILED DESCRIPTION

For simplicity, elements that are identical or have the same function bear the same references in the various embodiments.

### System

One object of the disclosure is a system for deforming an effective structure 1 including:
a stack comprising successively the effective structure 1 and a buffer matrix 2, the stack having an interface between the effective structure 1 and the buffer matrix 2, the interface having a mean plane;
compression means designed to apply a compressive force F to the stack along an axis Z′-Z normal to the mean plane of interface; and
shear means designed to apply to the buffer matrix 2 longitudinal shear forces f parallel to the mean plane of the interface;

the buffer matrix 2 being designed to transmit the shear forces f to the effective structure 1 in the mean plane of the interface so as to deform the effective structure 1.

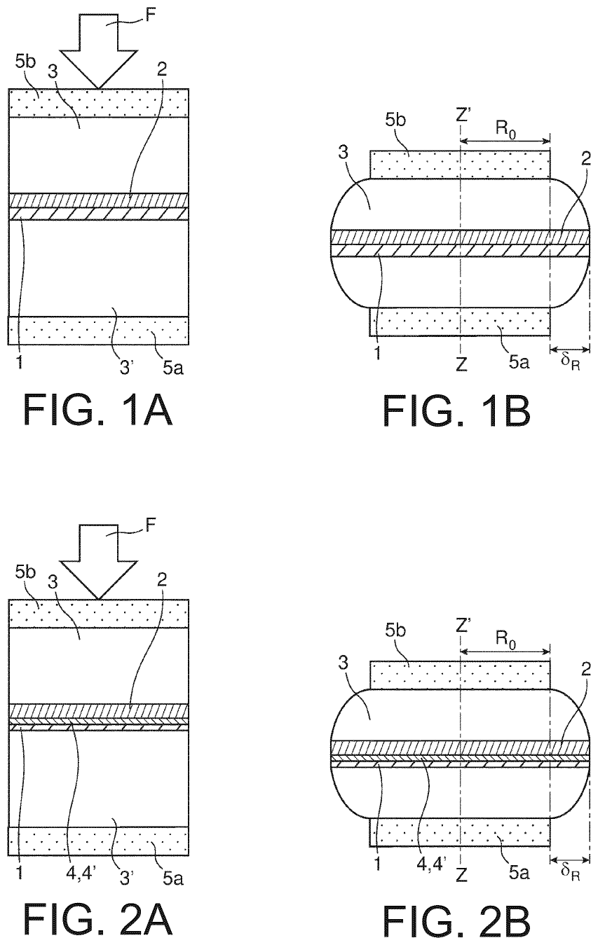

The lengthening (or shortening) δ_{R} of the effective structure 1 relative to its initial length R₀ along a longitudinal axis of the shear forces f is depicted in FIGS. 1B, 2B, 6B, and 7B.

### Stack

The effective structure 1 has a deformation rate at rupture denoted τ_{R1}. The effective structure 1 may be chosen from:
a structure based on a semiconductor type material;
a structure based on a perovskite type material;
a photonic crystal type structure;
a structure based on a composite material;
a crystal;
a metal;
a polymer;
a ceramic;
chalk; and
cement.

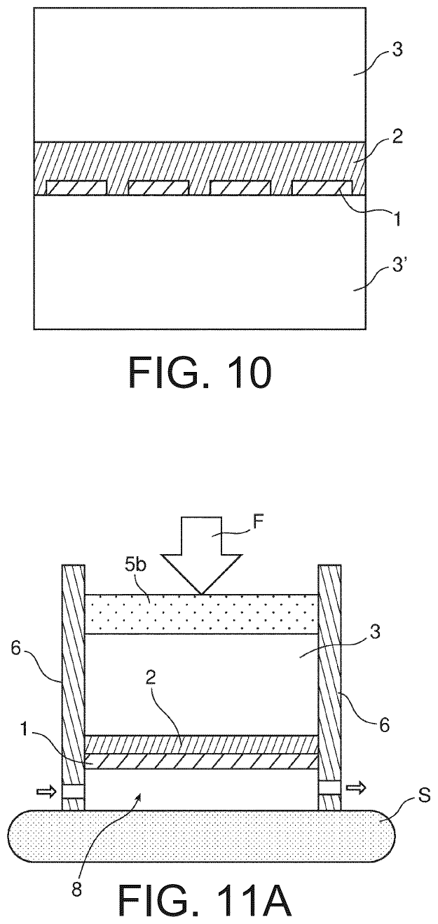

The material to be deformed of the effective structure 1 is solid. By way of non-limiting examples, the effective structure 1 may be produced in the form of a thin or thick film, a film structured in patterns (as depicted in FIG. 10), an array of nanometer filaments, a two-dimensional (2D) material including one to a few atomic monolayers. An advantage obtained by a film structured in patterns is to enable the elastic deformation limit to be increased. In fact, the elastic deformation limit of a structure depends on its geometry. The area of the effective section (on the section plane normal to the axis Z′-Z of the compression force F) varies in a manner inversely correlated with the elastic deformation limit. The effective structure 1 advantageously has a geometry compatible with microtechnologies/nanotechnologies. In other words, the effective structure 1 may have a thickness between a few nm and a few μm inclusive. By “thickness” is meant the dimension along the axis Z′-Z normal to the mean plane of the interface between the effective structure 1 and the buffer matrix 2. The effective structure 1 may nevertheless be macroscopic. When the effective structure 1 is macroscopic its area may be several tens of cm². By way of non-limiting example, the effective structure 1 may be a layer of silicon having a thickness between 200 nm and 2 μm inclusive.

The buffer matrix 2 advantageously has a Young's modulus greater than or equal to 1 GPa. The buffer matrix 2 has a deformation rate at rupture, denoted τ_{R2}, advantageously complying with the condition τ_{R2}>τ_{R1}. The buffer matrix 2 is advantageously made from a material chosen from:
a polymer, preferably a polyimide, polycarbonate, polyetherimide, polyamide-imide, polyethylene, glass, polyetheretherketone, polypropylene, polymethylmethacrylate, polyethersulfone, polyvinyl chloride, polystyrene, polyethylene terephthalate; and
a ceramic, preferably SiN, SiC, Al₂O₃.

The stack advantageously includes a rubbery layer 3, the buffer matrix 2 being situated between the effective structure 1 and the rubbery layer 3. The rubbery layer 3 is advantageously made of a material chosen from:
a silicone type polymer preferably including polydimethylsiloxane (PDMS);
vinyl ethylene acetate;
polyurethane;
polyacrylic;
butadiene;
a compound including a butyl group;
a rubber of EPDM type;
a fluoroelastomer, in particular a perfluoroelastomer;
isoprene;
a compound including a nitrile group;
polychloroprene; and
styrene-butadiene.

When the buffer matrix 2 is a polyimide film and the rubbery layer 3 is made of PDMS, the rubbery layer 3 may be bonded to the buffer matrix 2 with the aid of the unique reagent 3-mercaptopropyl trimethoxysilane (MPTMS) at room temperature. When the effective structure 1 is a layer of silicon, the polyimide film may be bonded to the effective structure 1 with the aid of an adhesive (e.g., HD3007 or HD3008 from HD Microsystems™).

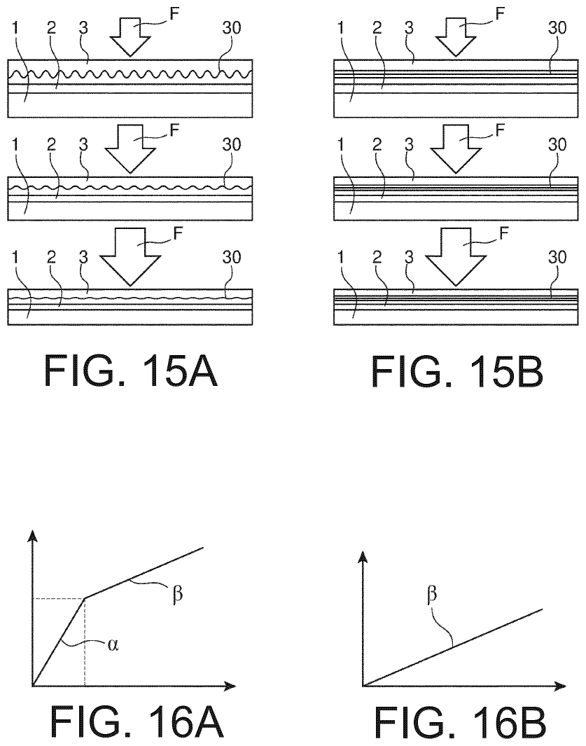

As depicted in FIG. 14 and in FIGS. 15A and 15B, the stack may include a rigid material 30 buried in the rubbery layer 3. By “rigid” is meant that the rigid material 30 has a Young's modulus greater than or equal to 100 MPa, preferably greater than or equal to 1 GPa. The rigid material 30 is geometrically designed to have different tensile strengths on the axes X and Y, as depicted in FIGS. 16A and 16B, based on a single compression force F applied to the stack along the axis Z′-Z normal to the mean plane of the interface. In fact, as depicted in FIG. 16A, starting from the compression force F threshold the tensile strength along the axis X corresponds to the sum of the coefficients α and β, whereas the tensile strength along the axis Y corresponds to the coefficient β, as depicted in FIG. 16B. By way of non-limiting example, the rigid material 30 may be a polymer, preferably a polyimide when the rubbery layer 3 is made of PDMS. When the effective structure 1 is compressed vertically, the resulting lateral deformations along the axes X and Y differ because of the undulations of the rigid material 30. The rigid material 30 with undulations does not modify the resistance to elongation along the axis X as long as the rigid material 30 is not “unfolded”, whereas the rigid material 30 has a resistance to elongation along the axis Y independent of its undulations. Starting from a certain degree of compression, the undulations of the rigid material 30 disappear. The resistances to elongation along the two axes X and Y become comparable. As depicted in FIGS. 16A and 16B, the deformation is at first rapid along the axis X because, along this axis, the rigid material 30 is unfolded without offering any resistance. As soon as the rigid material 30 is unfolded by the effect of the vertical pressure, the resistance of the rigid material 30 appears along the axis X. The slope then becomes identical to that showing the variation along the axis Y, the resistance to deformation of which is not linked to the presence or the state of the undulations.

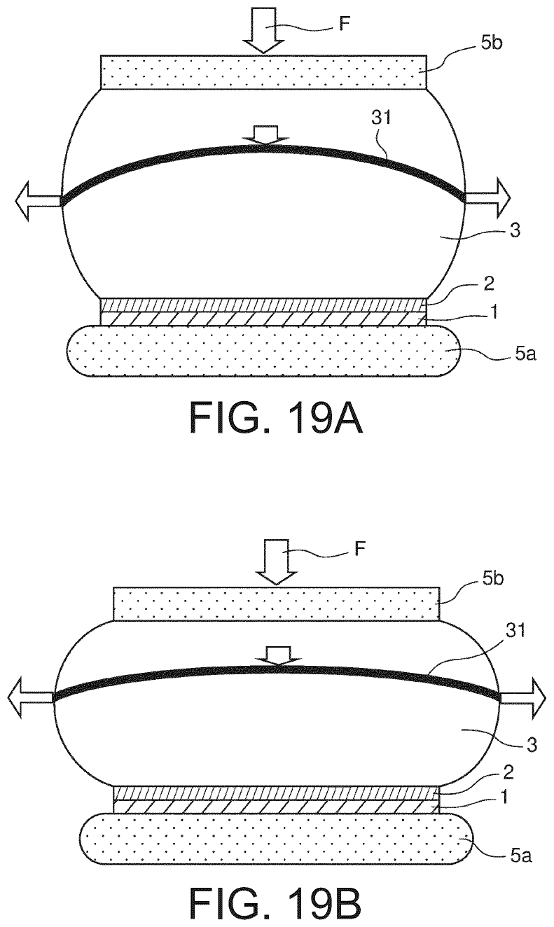

As depicted in FIGS. 19A and 19B, the stack may include a reinforcement 31 made of a rigid material and integrated into the rubbery layer 3, for example by a molding process. The reinforcement 31 may have a Young's modulus of the order of 1 GPa. The reinforcement 31 may have a thickness of a few hundred μm. The reinforcement 31 has a non-plane surface. The reinforcement 31 may have different profiles along axes defining a plane parallel to the mean plane of the interface between the effective structure 1 and the buffer matrix 2. Because of the action of the compression force F, the reinforcement 31 is flattened in such a manner as to favor the deformation in tension of the buffer matrix 2 and thereby of the effective structure 1. The reinforcement 31 may have a varying thickness (i.e., its dimension normal to the mean plane of the interface between the buffer matrix 2 and the effective structure 1) in such a manner as to allow non-homogeneous deformation.

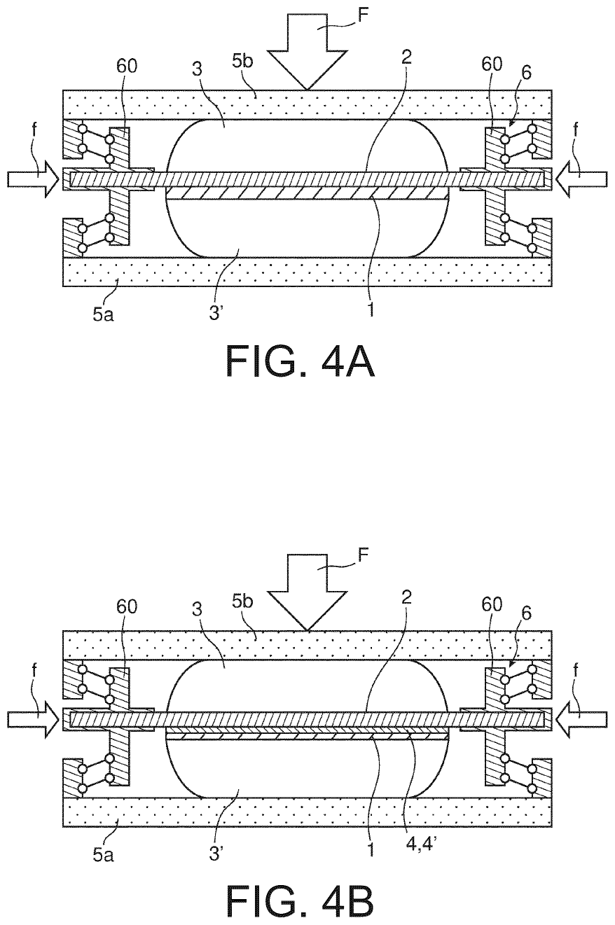

As depicted in FIGS. 2A, 2B, 3B, 4B, 5B, 7A, 7B, 8B, and 9B, the stack may include an anti-sliding layer 4 between the effective structure 1 and the buffer matrix 2, the anti-sliding layer 4 having a coefficient of friction designed to retain the effective structure 1 in position in the stack. Alternatively, the stack may include a bonding film 4′ between the effective structure 1 and the buffer matrix 2.

### Compression Means

The compression means may include a lower plate 5a and an upper plate 5b designed to fit tightly around the stack.

The lower plate 5a and the upper plate 5b are rigid. By “rigid” is meant that the lower plate 5a and the upper plate 5b have a Young's modulus greater than or equal to 100 MPa, preferably greater than or equal to 1 GPa.

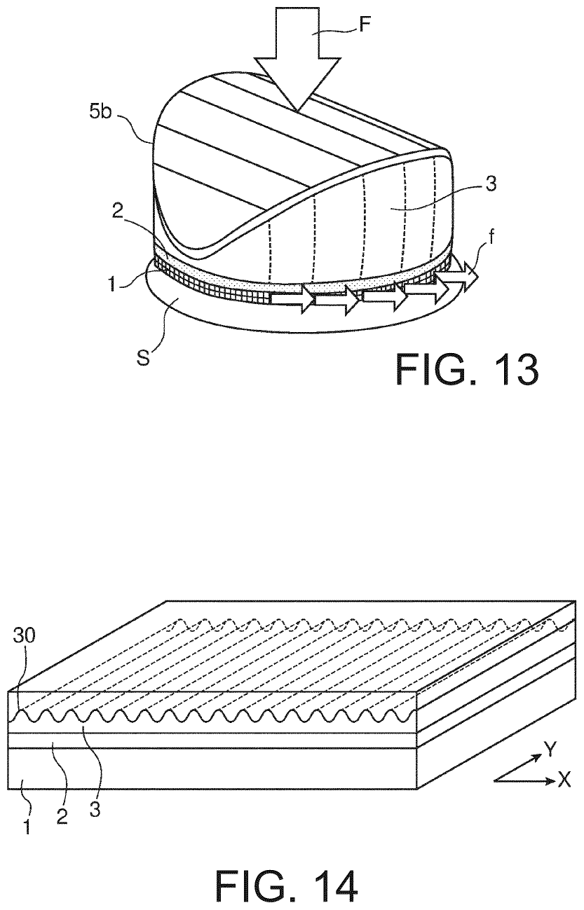

As depicted in FIGS. 12 and 13, the upper plate 5b can have a non-plane surface in contact with the rubbery layer 3, the non-plane contact surface being geometrically designed so that the rubbery layer 3 converts the compression force F into longitudinal shear forces f parallel to the mean plane of the interface applied in an anisotropic manner to the buffer matrix 2. This is referred as deformation of the effective structure 1 with geometric frustration.

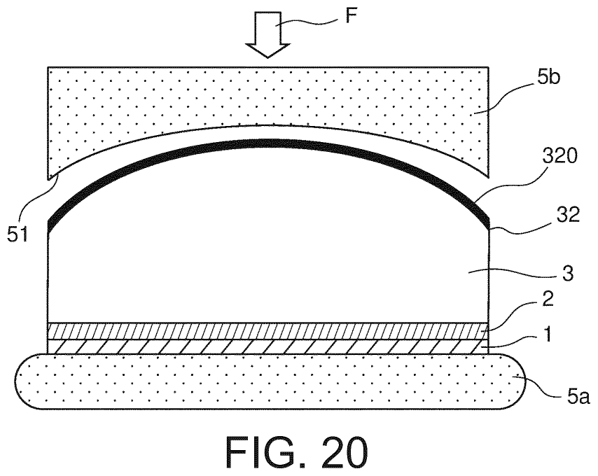

As depicted in FIG. 20, the rubbery layer 3 may be surmounted by a polymer layer 32 having a non-planar surface 320. The upper plate 5b may have a non-planar surface 51 intended to be in contact with the polymer layer 32. The non-planar surface 320 of the polymer layer 32 may have a shape different from that of the non-planar surface 51 of the upper plate 5b. The different shapes of the non-planar surface 51 of the upper plate 5b and of the non-planar surface 320 of the polymer layer 32 may be designed to obtain a dissymmetry of the deformation engendered, which may, for example, be uniaxial in compression along one axis or in tension along another axis. The polymer layer 32 formed on the rubbery layer 3 has a Young's modulus strictly greater than the Young's modulus of the rubbery layer 3.

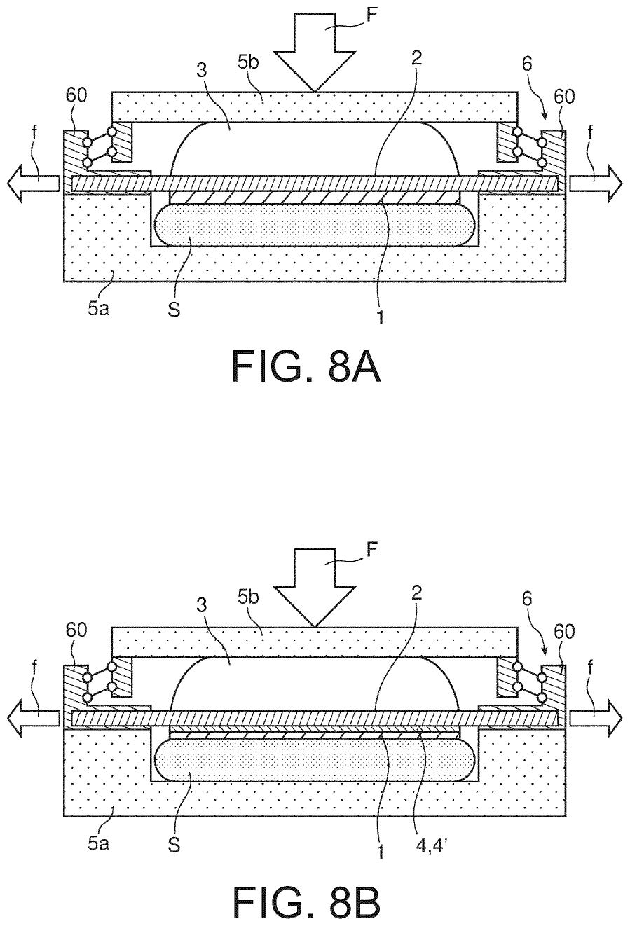

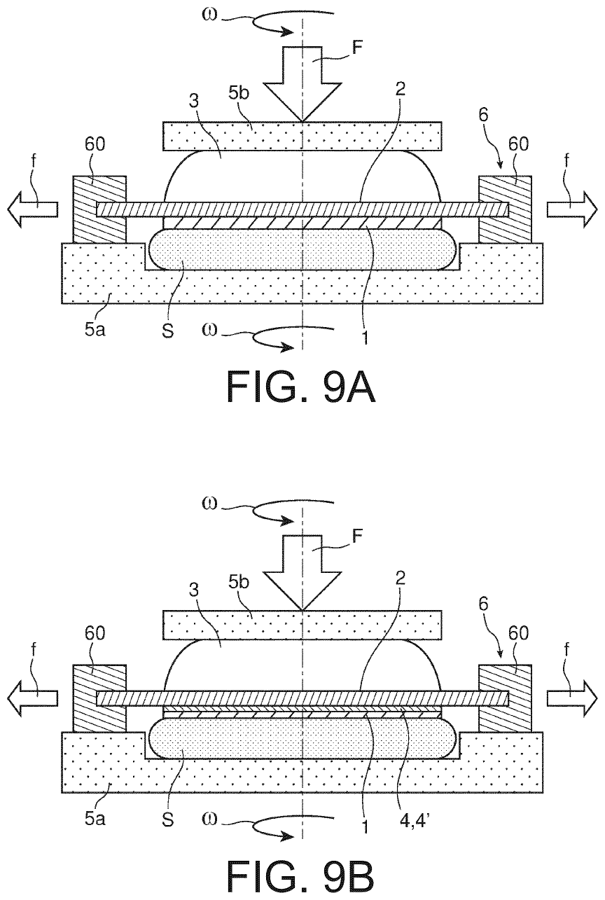

As depicted in FIGS. 8A, 8B, 9A, and 9B, the lower plate 5a can take the form of a frame designed to receive the stack.

### Shear Means

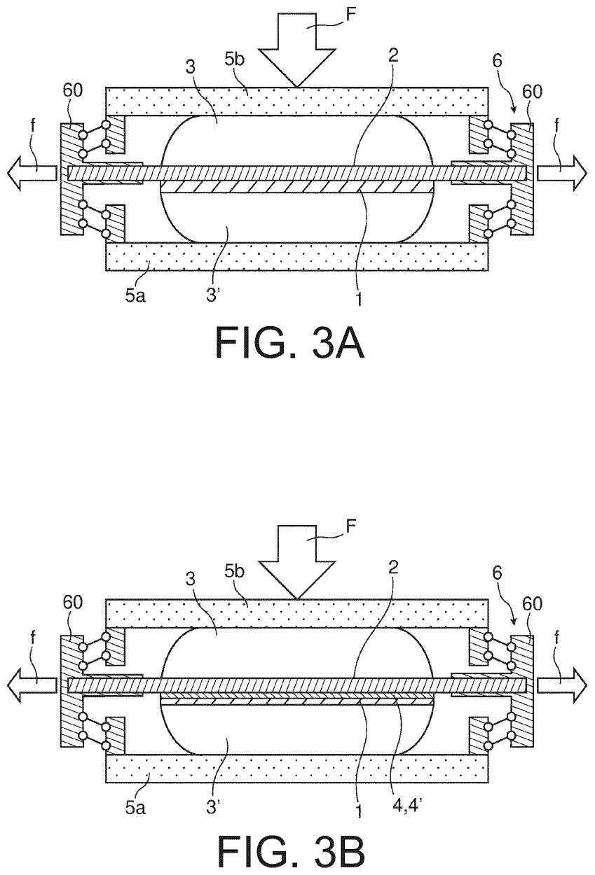

As depicted in FIGS. 3A, 3B, 4A, 4B, 8A, 8B, 9A, and 9B, the shear means may include a member 6 for holding the buffer matrix 2 mobile in translation in a longitudinal direction parallel to the mean plane of the interface. The shear means advantageously include an articulated parallelogram designed to move the holding member 6 in translation in the longitudinal direction. The holding member 6 is advantageously mobile in rotation about a rotation axis ω perpendicular to the mean plane of the interface. The holding member 6 may include two holding arms 60 arranged at the lateral sides of the buffer matrix 2. As depicted in FIGS. 8A, 8B, 9A, and 9B, the holding member 6 may be mounted on a frame 5a (also referred to herein as the lower plate 5a). The frame 5a is advantageously mobile in rotation about a rotation axis ω perpendicular to the mean plane of the interface. It is therefore possible to deform the effective structure 1 thanks to the centrifugal force produced by the rotation. The addition of weight at the periphery of the buffer matrix 2 makes it possible to increase the centrifugal force. Shear means of this kind are external to the stack.

The shear means advantageously include the rubbery layer 3, the rubbery layer 3 being designed to convert the compression force F into longitudinal shear forces f parallel to the mean plane of the interface applied to the buffer matrix 2. Shear means of this kind are internal to the stack and can coexist with shear means external to the stack, which makes it possible to envisage biaxial (possibly anisotropic) deformation of the effective structure 1 in the mean plane of the interface between the effective structure 1 and the buffer matrix 2. It is equally possible to use only shear means internal to the stack and to dispense with shear means external to the stack.

The shear means may include a rigid structure around the rubbery layer 3 to control the deformation of the rubbery layer 3. To be more precise, the rigid structure is geometrically designed to control the deformation of the rubbery layer 3 in a plane parallel to the mean plane of the interface, during conversion of the compression force F into longitudinal shear forces f parallel to the mean plane of the interface applied to the buffer matrix 2. A rigid structure of this kind makes it possible to prevent biaxial deformations of the effective structure 1 in some directions in the mean plane of the interface between the effective structure 1 and the buffer matrix 2. By way of non-limiting example, the rigid structure may be produced with the aid of a mold. By “rigid” is meant that the rigid structure has a Young's modulus greater than or equal to 100 MPa, preferably greater than or equal to 1 GPa.

### Additional Equipment

The system may include an enclosure designed to receive the stack. The enclosure may include walls designed to allow access to the compression means and where applicable to the shear means external to the stack, in order to be able to actuate them. An enclosure of this kind makes it possible to apply to the stack a heat treatment (e.g., stoving), for example to obtain a particular operating point of the effective structure 1. By way of illustration, the electrical conductivity of the effective structure 1 may vary as a function of temperature.

The system advantageously includes fixed lateral walls designed to fit tightly around the rubbery layer 3 laterally. Lateral walls of this kind may be part of a mold. Lateral walls of this kind make it possible to control the lateral deformation of the rubbery layer 3. This is referred to as frustrated deformation. It is equally possible to provide a lubricant between the lateral walls and the stack.

### Characterization Assembly

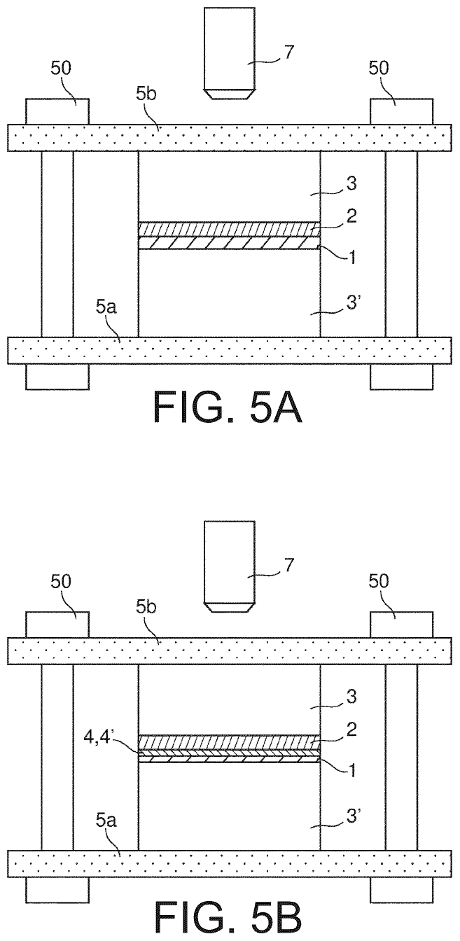

As depicted in FIGS. 5A and 5B, one object of the disclosure is an assembly for characterization of an effective structure 1 to be deformed including:
a system in accordance with embodiments of the disclosure; and
a characterization instrument 7 designed to measure the deformation of the effective structure 1, the characterization instrument 7 preferably being chosen from:
   a spectroscope, preferably an X-ray diffractometer, a Raman spectrometer, a photoluminescence spectroscope, a reflectance spectroscope; and
   an instrument for measuring electrical resistivity, preferably by the four-point method or by the Van der Pauw method.

Other spectrometry techniques are possible: absorption of light, absorption of X-rays, etc.

In accordance with one embodiment:
the compression means include a lower plate 5a and an upper plate 5b designed to fit tightly around the stack;
the stack includes:
   a first rubbery layer 3 between the buffer matrix 2 and the upper plate 5b; and
   a second rubbery layer 3′ between the lower plate 5a and the effective structure 1;
   the stack having an additional interface between the effective structure 1 and the second rubbery layer 3′, the additional interface having a mean plane;
the shear means include the first rubbery layer 3, the first rubbery layer 3 being designed to convert the compression force F into longitudinal shear forces f parallel to the mean plane of the interface applied to the buffer matrix 2; and
the second rubbery layer 3′ is designed to convert the compression force F into longitudinal shear forces f applied to the effective structure 1 in the mean plane of the additional interface.

By way of non-limiting examples, the upper plate 5b can be made of polymethylmethacrylate (PMMA) and the lower plate 5a can be made of a metal such as Al. PMMA is advantageous in terms of rigidity and transparency (in particular, in the visible domain). As depicted in FIGS. 5A and 5B, the compression means may include two clamping screws 50 the clamping torque of which can be measured with the aid of a dynamometer screwdriver.

The first and second rubbery layers 3, 3′ are advantageously made of a material chosen from:
a silicone type polymer preferably including polydimethylsiloxane (PDMS);
vinyl ethylene acetate;
polyurethane;
polyacrylic;
butadiene;
a compound including a butyl group;
a rubber of EPDM type;
a fluoroelastomer, in particular a perfluoroelastomer;
isoprene;
a compound including a nitrile group;
polychloroprene; and
styrene-butadiene.

If the first and second rubbery layers 3, 3′ are made of PDMS, it is not necessary to bond them to the upper plate 5b and the lower plate 5a respectively. In fact, because of its low Young's modulus PDMS has a very high coefficient of friction.

As depicted in FIG. 12, the lower plate 5a may have a non-plane surface in contact with the second rubbery layer 3′, the non-plane contact surface being geometrically designed so that the second rubbery layer 3′ converts the compression force F into longitudinal shear forces f applied in an anisotropic manner to the effective structure 1 in the mean plane of the additional interface.

### Fabrication Assembly No. 1

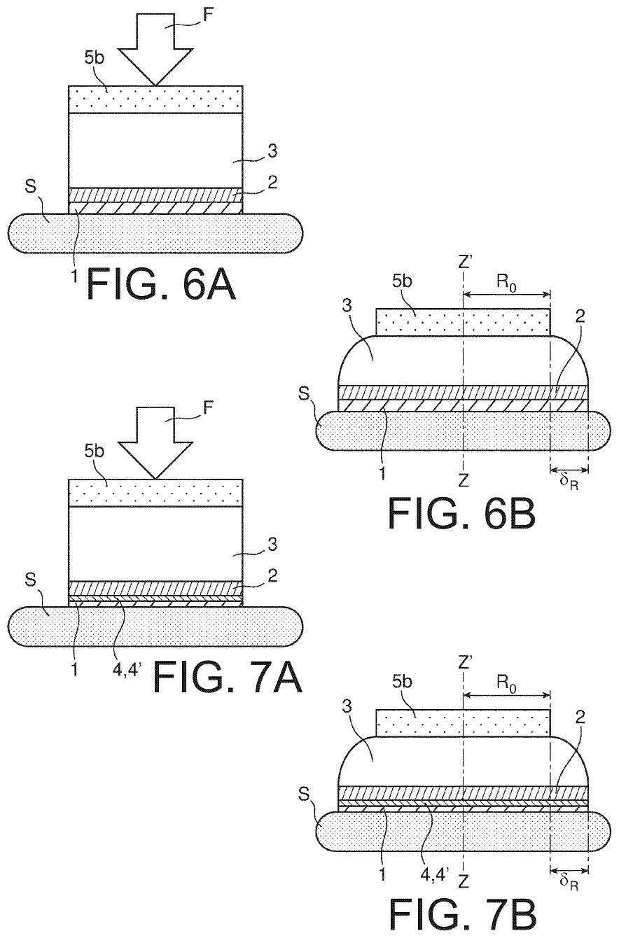

As depicted in FIGS. 6A, 6B, 7A, 7B, 8A, 8B, 9A, 9B, 11A, and 11B, an object of the disclosure is an assembly for fabrication of a deformed effective structure 1 on a support substrate S, the fabrication assembly including:
a system in accordance with embodiments of the disclosure; and
the support substrate S;

the stack being formed on the support substrate S.

By way of non-limiting examples, the support substrate S may be made of a material chosen from Si, Ge, Al₂O₃ (sapphire), glass.

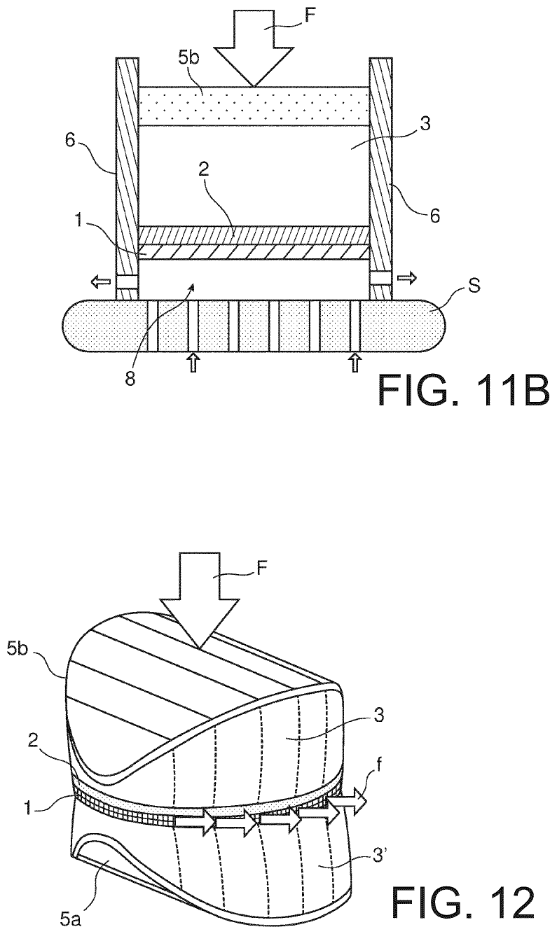

As depicted in FIGS. 11A and 11B, the stack may include a layer 8 of air below the effective structure 1 designed to space the effective structure 1 from the support substrate S. The holding member 6 for the buffer matrix 2 is advantageously situated on the lateral edges of the stack in such a manner as to delimit the layer 8 of air. After deformation of the effective structure 1, the air may be removed from the layer 8 of air, for example by vacuum means, to obtain adhesion of the stack on the support substrate S.

In an embodiment depicted in FIG. 11B, the support substrate S is permeable to air and the fabrication assembly includes circulation means designed to circulate a flow of air from the support substrate S toward the layer 8 of air, so that the flow of air generates a sustentation force holding the effective structure 1 in position in the stack. The circulation means advantageously include a regulator designed to regulate the flow of air circulating in the layer 8 of air. The regulator may include an air compressor.

In a variant of the layer 8 of air, the support substrate S may include a temporary bonding film on which the stack is formed. The temporary bonding film may be made of a material the change of phase of which can be controlled. The temporary bonding film may be subjected to a heat treatment designed to prevent definitive bonding and to allow longitudinal sliding of the effective structure 1 (in the mean plane of the interface between the temporary bonding film and the effective structure 1).

In this regard, the fabrication assembly may include an enclosure designed to receive the system and the support substrate S. The enclosure may include walls designed to allow access to the compression means, and where appropriate to the shear means external to the stack, in order to be able to actuate them. An enclosure of this kind makes it possible, in particular, to apply a heat treatment to the temporary bonding film (e.g., a thermoplastic polyimide), the heat treatment being designed to modify the mechanical properties of the temporary bonding film in such a manner as to allow longitudinal sliding of the effective structure 1 to deform it. Lowering the temperature of the heat treatment makes it possible to polymerize the temporary bonding film again and to fix the deformed state of the effective structure 1. In accordance with a variant embodiment, a heat treatment (e.g., at a temperature between 80° C. and 120° C.) is applied to the support substrate S and to the temporary bonding film to limit the energy of adhesion between the effective structure 1 and the temporary bonding film, in order to obtain a sliding interface between the effective structure 1 and the temporary bonding film. When the effective structure 1 is deformed, the bonding between the effective structure 1 and the temporary bonding film is optimized, either by cooling the assembly to room temperature (direct bonding) or by heating the assembly to 300° C. while exerting a bonding pressure (thermocompression).

After the effective structure 1 has been deformed on the support substrate S, the elements covering the effective structure (e.g., the anti-sliding layer 4, the buffer matrix 2, the rubbery layer 3) may be removed so as to expose the effective structure 1. The deformed effective structure 1 may be transferred onto a final substrate, for example via oxide-oxide (e.g., SiO₂) bonding, possibly using a plasma (e.g., O, O₂). The support substrate S is then removed in order to complete the transfer of the deformed effective structure 1.

### Fabrication Assembly No. 2

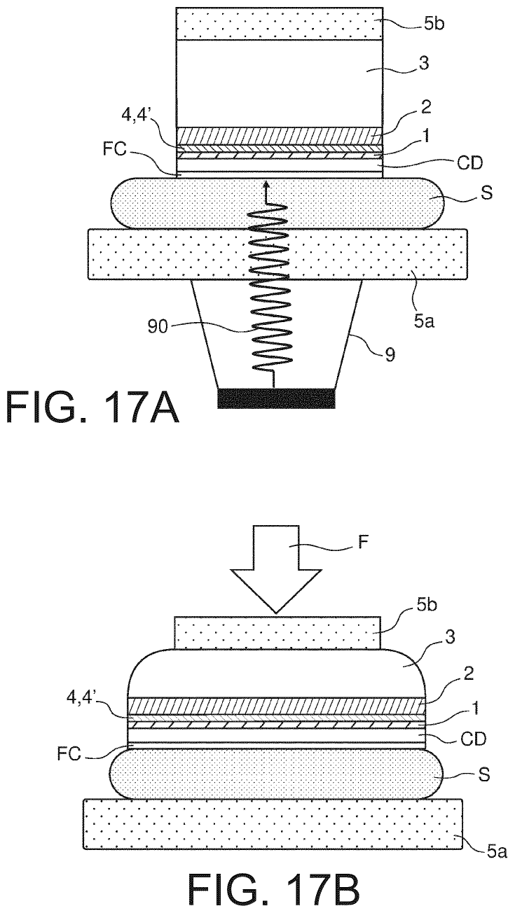

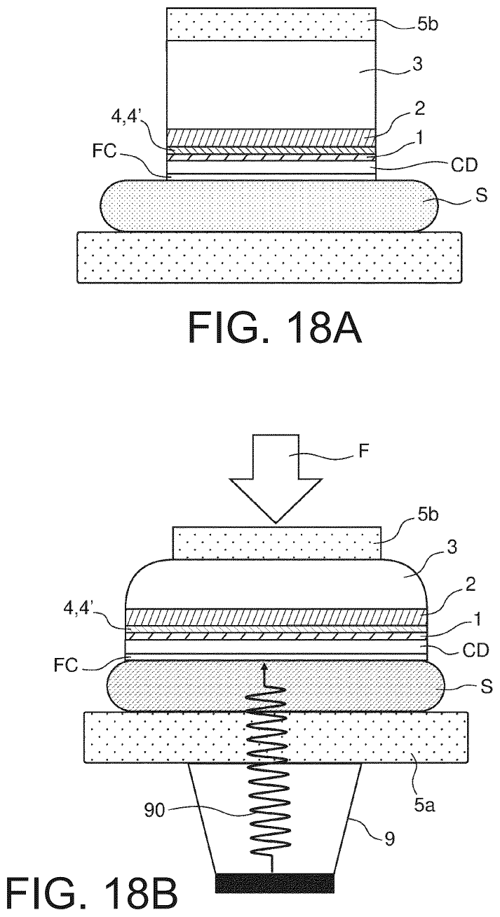

As depicted in FIGS. 17A, 17B, 18A, and 18B, one object of the disclosure is an assembly for fabrication of a deformed effective structure 1 on a support substrate S, the fabrication assembly including:
a stack including successively the support substrate S, a bonding film FC, the effective structure 1 and a buffer matrix 2, the stack including an interface between the effective structure 1 and the buffer matrix 2, the interface having a mean plane;
compression means designed to apply to the stack a compression force F along the axis Z′-Z normal to the mean plane of the interface; and
shear means designed to apply to the buffer matrix 2 longitudinal shear forces f parallel to the mean plane of the interface;

the buffer matrix 2 being designed to transmit the shear forces f to the effective structure 1 in the mean plane of the interface in such a manner as to deform the effective structure 1.

The stack can be obtained using a support substrate S of semiconductor-on-polymer (SoP) type on which the buffer matrix 2 is formed. The semiconductor layer 2 of the support substrate S of SoP type forms the effective structure 1. The polymer layer of the support substrate S of SoP type forms the bonding film FC.

The stack may include a bonding film 4′ between the effective structure 1 and the buffer matrix 2, having an anti-sliding function.

The compression means may include a lower plate 5a and an upper plate 5b designed to fit tightly around the stack.

The fabrication assembly may include a detachment layer CD between the bonding film FC and the effective structure 1, the detachment layer CD being designed to detach the support substrate S when the detachment layer CD is subjected to a heat treatment. By way of non-limiting example, the detachment layer CD may be made of a thermoplastic material. An alternative is for the bonding film FC to have an intrinsic detachment function.

The bonding film FC is advantageously made of a polymer material. The fabrication assembly may include emission means 9 designed to emit electromagnetic radiation 90 through the substrate support S in such a manner as to irradiate the bonding film FC, the support substrate S being transparent to the electromagnetic radiation 90. By way of non-limiting example, the support substrate S may be made of glass or of sapphire.

In accordance with one embodiment, the bonding film FC is made of a thermoplastic polymer (e.g., a polyimide) and the emission means 9 are designed to emit infrared electromagnetic radiation 90 at a wavelength that may be of the order of 1 μm. The thermoplastic polymer is opaque to infrared. This embodiment enables so-called “cold wall” heating of the bonding film FC. The electromagnetic radiation 90 passes through the materials of the stack transparent to infrared and heats in a targeted manner the materials opaque to infrared of the stack. The emission means 9 may include an infrared lamp below the lower plate 5a. The emission means 9 are deactivated to fix the deformed state of the effective structure 1.

In accordance with one embodiment, the bonding film FC is made of a heatset polymer (e.g., an epoxy resin) and the emission means 9 are designed to emit ultraviolet electromagnetic radiation 90. The ultraviolet electromagnetic radiation 90 is activated to polymerize the bonding film FC in order to fix the deformed state of the effective structure 1.

The disclosure is not limited to the embodiments described. The person skilled in the art is in a position to consider technically operative combinations thereof and substitution of equivalents therefor.

1. A system for deforming an effective structure, comprising:
a stack comprising successively the effective structure and a buffer matrix, the stack having an interface between the effective structure and the buffer matrix, the interface having a mean plane;
a compression means designed to apply a compressive force to the stack along an axis normal to the mean plane of the interface; and
shear means designed to apply to the buffer matrix longitudinal shear forces parallel to the mean plane of the interface;
the buffer matrix being designed to transmit the shear forces to the effective structure in the mean plane of the interface so as to deform the effective structure.

2. The system of claim 1, wherein the shear means comprises a holding member for holding the buffer matrix mobile in translation in a longitudinal direction parallel to the mean plane of the interface.

3. The system of claim 2, wherein the shear means further comprises an articulated parallelogram designed to move the holding member in translation in the longitudinal direction.

4. The system of claim 2, wherein, the holding member is mobile in rotation about a rotation axis perpendicular to the mean plane of the interface.

5. The system of claim 1, wherein the stack further comprises a rubbery layer, the buffer matrix being between the effective structure and the rubbery layer, and the shear means including the rubbery layer, the rubbery layer being designed to convert the compression force into longitudinal shear forces parallel to the mean plane of the interface applied to the buffer matrix.

6. The system of claim 5, wherein the rubbery layer comprises a material chosen from:
a silicone-type polymer preferably including polydimethylsiloxane;
vinyl ethylene acetate;
polyurethane;
polyacrylic;
butadiene;
a compound including a butyl group;
a rubber of EPDM type;
a fluoroelastomer, in particular a perfluoroelastomer;
isoprene;
a compound including a nitrile group;
polychloroprene; and
styrene-butadiene.

7. The system of claim 1, wherein the buffer matrix has a Young's modulus greater than or equal to 1 GPa.

8. The system of claim 1, wherein the effective structure has a deformation rate at rupture denoted τ_{R1} and the buffer matrix has a deformation rate at rupture denoted τ_{R2} satisfying a condition τ_{R2}>τ_{R1}.

9. The system of claim 1, wherein the buffer matrix comprises a material chosen from:
a polymer, preferably a polyimide, polycarbonate, polyetherimide, polyamide-imide, polyethylene, glass, polyetheretherketone, polypropylene, polymethylmethacrylate, polyethersulfone, polyvinyl chloride, polystyrene, polyethylene terephthalate; and
a ceramic, preferably SiN, SiC, Al₂O₃.

10. The system of claim 1, wherein the effective structure is chosen from:
a structure based on a semiconductor type material;
a structure based on a perovskite type material;
a photonic crystal type structure;
a structure based on a composite material;
a crystal;
a metal;
a polymer;
a ceramic;
chalk; and
cement.

11. The system of claim 1, wherein the compression means include a lower plate and an upper plate designed to fit tightly around the stack.

12. The system of claim 1, wherein
the stack further comprises a rubbery layer, the buffer matrix being between the effective structure and the rubbery layer, and the shear means including the rubbery layer, the rubbery layer being designed to convert the compression force into longitudinal shear forces parallel to the mean plane of the interface applied to the buffer matrix; and
the upper plate has a non-planar contact surface in contact with the rubbery layer, the non-planar contact surface being geometrically designed so that the rubbery layer converts the compression force into longitudinal shear forces parallel to the mean plane of the interface applied anisotropically to the buffer matrix.

13. The system of claim 1, wherein the stack further comprises an anti-sliding layer between the effective structure and the buffer matrix, the anti-sliding layer having a coefficient of friction designed to hold the effective structure in position in the stack.

14. The system of claim 1, wherein the stack further comprises a bonding film between the effective structure and the buffer matrix.

15. An assembly for characterization of an effective structure to be deformed, including:
the system of claim 1;
a characterization instrument designed to measure the deformation of the effective structure, the characterization instrument preferably being chosen from:
a spectroscope, preferably an X-ray diffractometer, a Raman spectrometer, a photoluminescence spectroscope, or a reflectance spectroscope; and
an instrument for measuring electrical resistivity, preferably by the four-point method or by the Van der Pauw method.

16. The assembly of claim 15, wherein:
the compression means comprises a lower plate and an upper plate designed to fit tightly around the stack;
the stack further comprises:
a first rubbery layer between the buffer matrix and the upper plate; and
a second rubbery layer between the lower plate and the effective structure;
the stack having an additional interface between the effective structure and the second rubbery layer, the additional interface having a mean plane;
the shear means comprises the first rubbery layer, the first rubbery layer being designed to convert the compression force into longitudinal shear forces parallel to the mean plane of the interface applied to the buffer matrix; and
the second rubbery layer is designed to convert the compression force into longitudinal shear forces applied to the effective structure in the mean plane of the additional interface.

17. An assembly for fabrication of a deformed effective structure on a support substrate, the assembly comprising:
the system of claim 1; and
the support substrate;
the stack being formed on the support substrate.

18. The assembly of claim 17, wherein the stack further comprises a layer of air below the effective structure designed to space the effective structure from the support substrate.

19. The assembly of claim 18, wherein the support substrate is permeable to air, the assembly further comprising circulation means designed to cause a flow of air to circulate from the support substrate toward the layer of air so that the flow of air generates a sustentation force holding the effective structure in position in the stack.

20. The assembly of claim 19, wherein the circulation means comprises a regulator designed to regulate the flow of air circulating in the layer of air.

21. An assembly for fabrication of a deformed effective structure on a support substrate, the assembly comprising:
a stack comprising successively the support substrate, a bonding film, the effective structure, and a buffer matrix, the stack having an interface between the effective structure and the buffer matrix, the interface having a mean plane;
compression means designed to apply a compressive force to the stack along an axis normal to the mean plane of the interface; and
shear means designed to apply to the buffer matrix longitudinal shear forces parallel to the mean plane of the interface;
the buffer matrix being designed to transmit the shear forces to the effective structure in the mean plane of the interface so as to deform the effective structure.

22. The assembly of claim 21, further comprising a detachment layer between the bonding film and the effective structure, the detachment layer being designed to detach the support substrate when the detachment layer is subjected to a heat treatment.

23. The assembly of claim 21, wherein the bonding film comprises a polymer material, the assembly further comprising emission means designed to emit electromagnetic radiation through the support substrate in such a manner as to irradiate the bonding film, the support substrate being transparent to the electromagnetic radiation.
